(19) United States
(12) Patent Application Publication
(10) Pub. No.: US 2025/0301719 A1
(43) Pub. Date: Sep. 25, 2025

(54) SEMICONDUCTOR DEVICE AND METHOD OF FORMING THE SAME

(71) Applicant: NANYA TECHNOLOGY CORPORATION, New Taipei city (TW)

(72) Inventor: Ying-Cheng CHUANG, New Taipei City (TW)

(21) Appl. No.: 18/612,241

(22) Filed: Mar. 21, 2024

(51) Int. Cl. H01L 29/06; H01L 21/28; H01L 21/768; H01L 23/64; H01L 29/423; H01L 29/66

(52) U.S. Cl. CPC H10D 62/102; H01L 21/28088; H01L 21/76831; H01L 23/647; H10D 64/017; H10D 64/513; H10D 64/514

(57) ABSTRACT

A semiconductor device includes a substrate, an active region and a gate structure. The active region is located in the substrate and the gate structure is located in the active region. The gate structure includes a bottom lining layer, a bottom low work function material layer formed in the bottom lining layer, and a bottom conductive material layer formed in the bottom low work function material layer. In addition, a method of forming the semiconductor device is also disclosed.

### BACKGROUND

### Field of Invention

The present invention relates to a semiconductor device and a method of forming the same. More particularly, the present disclosure relates to a memory device and a method of forming the same.

### Description of Related Art

In recent decades, demand to storage capability has increased as electronic products continue to improve. In order to increase storage capability of a memory device (e.g., a DRAM device), more memory cells are integrated in the memory device. As the integration level increases, the fabrication process of the memory device may become much more complicated, and the process window may become rather narrow.

As electronic devices become lighter and thinner, semiconductor devices, such as dynamic random access memory (DRAM) become more highly integrated. Further, the performance of the DRAM is improved via shortening the pitch between the semiconductor structures in the DRAM. Due to shrinking the size of the semiconductor structure, in addition to increasing the difficulty of the manufacturing process, the components in the semiconductor structures are also prone to leakage resulting from too close distances.

As a result, in the semiconductor manufacturing process, how to reduce the leakage to improve the process yield of the semiconductor structure has become an important issue.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a semiconductor device and a method of forming the same able to improve a gate induced drain leakage current (GIDL) and reduce the resistance of the word line.

To achieve these and other advantages and in accordance with the objective of the embodiments of the present invention, as the embodiment broadly describes herein, the embodiments of the present invention provides a semiconductor device including a substrate, an active region and a gate structure. The active region is located in the substrate and the gate structure is located in the active region. The gate structure includes a bottom lining layer, a bottom low work function material layer formed in the bottom lining layer, and a bottom conductive material layer formed in the bottom low work function material layer.

In some embodiments, a material of the bottom conductive material layer includes titanium nitride.

In some embodiments, a material of the bottom low work function material layer includes a polycrystalline silicon or an amorphous silicon.

In some embodiments, a material of the bottom lining layer includes silicon oxide.

In some embodiments, the semiconductor device further includes a residual lining layer above the bottom lining layer and located higher than the bottom low work function material layer and the bottom conductive material layer.

In some embodiments, a thickness of the residual lining layer is thinner than a thickness of the bottom lining layer.

In some embodiments, the semiconductor device further includes a barrier layer formed in the residual lining layer.

In some embodiments, the semiconductor device further includes a dielectric layer formed in the barrier layer.

In some embodiments, the semiconductor device further includes an isolation region in the substrate and a dummy gate structure in the isolation region, and the dummy gate structure extends deeper than the gate structure in the substrate.

In some embodiments, the isolation region includes an oxide layer directly in contact with the active region and a nitride layer sandwiched by the oxide layer.

In another aspect of the present invention is to provide a method of forming a semiconductor device including forming an active region and an isolation region in a substrate, forming a trench in the active region with a hark mask layer, depositing a lining layer in the trench, depositing a low work function material layer in the trench, and depositing a conductive material layer to fill the trench.

In some embodiments, the method of forming a semiconductor device further includes etching back the conductive material layer and the low work function material layer to form a bottom conductive material layer and a bottom low work function material layer surrounding the bottom conductive material layer.

In some embodiments, the method of forming a semiconductor device further includes performing a cleaning process to remove a portion of the lining layer above the hard mask layer, a portion of the lining layer on the sidewall of the trench to form a residual lining layer and a bottom lining layer.

In some embodiments, the bottom lining layer is sandwiched between the bottom low work function material layer and the active regions or between the bottom low work function material layer and the isolation region.

In some embodiments, a thickness of the residual lining layer is thinner than a thickness of the bottom lining layer.

In some embodiments, the method of forming a semiconductor device further includes depositing a barrier layer on the hard mask layer as well as in the trench.

In some embodiments, the barrier layer is conformally formed on a sidewall of the trench, and the top surfaces of the hard mask layer, the bottom low work function material layer, the bottom conductive material layer and the bottom lining layer.

In some embodiments, the barrier layer is formed by an atomic layer deposition process.

In some embodiments, the method of forming a semiconductor device further includes performing a directional etching process to remove lateral portions of the barrier layer above the hard mask layer and remain a residual barrier layer on a sidewall of the trench.

In some embodiments, the method of forming a semiconductor device further includes depositing a dielectric layer on the active region, the isolation region and the hard mask layer, and in the trenches.

Hence, the semiconductor device and the method of forming the same according to some embodiments of the present invention utilize the low work function material layer, e.g. a polycrystalline silicon layer or an amorphous silicon layer and a titanium nitride conductive material layer to effectively improve the gate-induced drain leakage current and reduce the resistance of the word line.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a schematic layout of a semiconductor device according to some embodiments of the disclosure; and

FIGS. 2-9 are cross-sectional views of different steps of a method of forming a semiconductor device, taken along line A-A in FIG. 1, according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

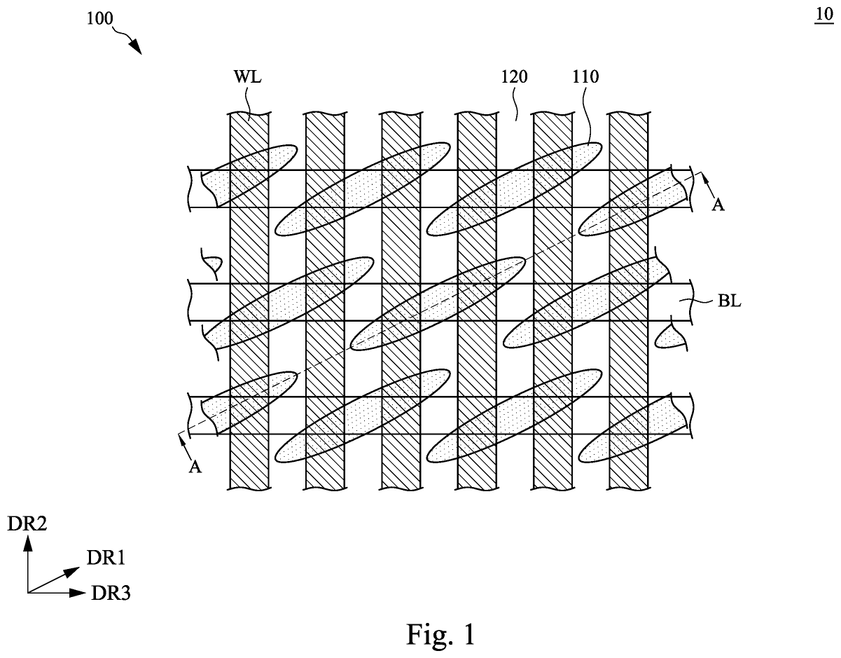

FIG. 1 is a schematic layout of a semiconductor device according to some embodiments of the disclosure. A dynamic random access memory (DRAM) array 10 is shown as an example of the semiconductor device 100 according to some embodiments of the disclosure. The semiconductor device 100 includes a plurality of active regions 110 that are defined by an isolation region 120 formed in a substrate. The active regions 110 may extend in a first direction DR1, a plurality of word lines WLs extend in a second direction DR2 which forms an angle with the first direction DR1, and a plurality of bit lines BLs extend in a third direction DR3 which forms an angle with the first direction DR1. In some embodiments, the shape of the active regions 110 can be an ellipse. The angle between the first direction DR1 and the second direction DR2 and the angle between the first direction DR1 and the third direction DR3 may be, but are not limited to, 45 and 45 degrees, 30 and 60 degrees, or 60 and 30 degrees, respectively. In some embodiments, the word lines WLs are formed perpendicular to the bit lines BLs. That is, the angle between the second direction DR2 and the third direction DR3 may be 90 degrees.

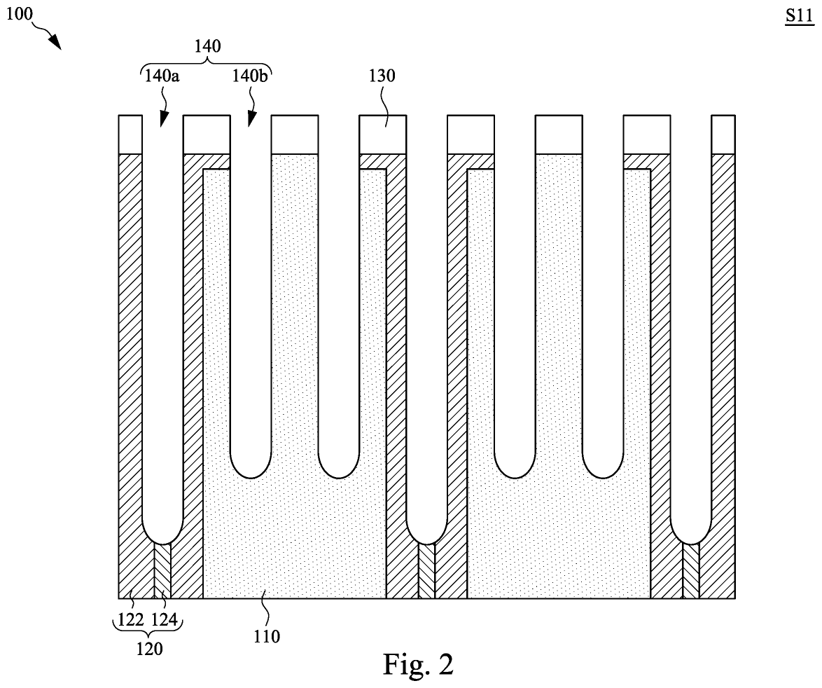

Reference is made to FIGS. 2-9, which are cross-sectional views of different steps of a method of forming a semiconductor device, taken along line A-A in FIG. 1, according to some embodiments of the disclosure. As shown in FIG. 2, the method begins at step S11. The semiconductor device 100 includes the active regions 110 defined by the isolation region 120. In some embodiments, the active regions 110 and the isolation region 120 are formed in the substrate, in which the substrate may be, for example, a silicon (Si) substrate. Alternatively, the substrate can be a Si substrate and is doped with other semiconductor materials. In some other embodiments, the substrate may include a layered semiconductor such as silicon/silicon germanium, silicon-on-insulator, or silicon germanium-on-insulator. In some embodiments, the active regions 110 may be doped with an N-type dopant such as phosphorus (P), arsenic (As), or antimony (Sb). In some other embodiments, the active regions 110 may be doped with a P-type dopant such as boron (B) or indium (In). In some embodiments, the substrate may be or include an unimplanted area. In some embodiments, the active regions 110 may have a higher doping concentration than the substrate.

The isolation region 120 is formed surrounding the active regions 110 to separate the active regions 110 from other. In some embodiments, the isolation region 120 is a multi-layer structure including an oxide layer 122 directly in contact with the active regions 110 and a nitride layer 124 sandwiched by the oxide layer 122. The multi-layer structure ensures a seamless isolation region 120 and provides better electrical isolation between the active regions 110.

A patterned hard mask layer 130 having a plurality of openings is formed on the substrate, and an etching process is performed through the openings to form plurality of trenches 140 in the active regions 110 and in the isolation region 120. In some embodiments, the trenches 140 are formed by performing a wet etching process or a dry etching process. Due to the etching selectivity of materials of the active regions 110 and the isolation region 120, the depth of the trenches 140 such as trenches 140a in the isolation region 120 is deeper than the trenches 140 such as trenches 140b in the active regions 110, and portions of the nitride layer 124 of the isolation region 120 is revealed from the trenches 140a.

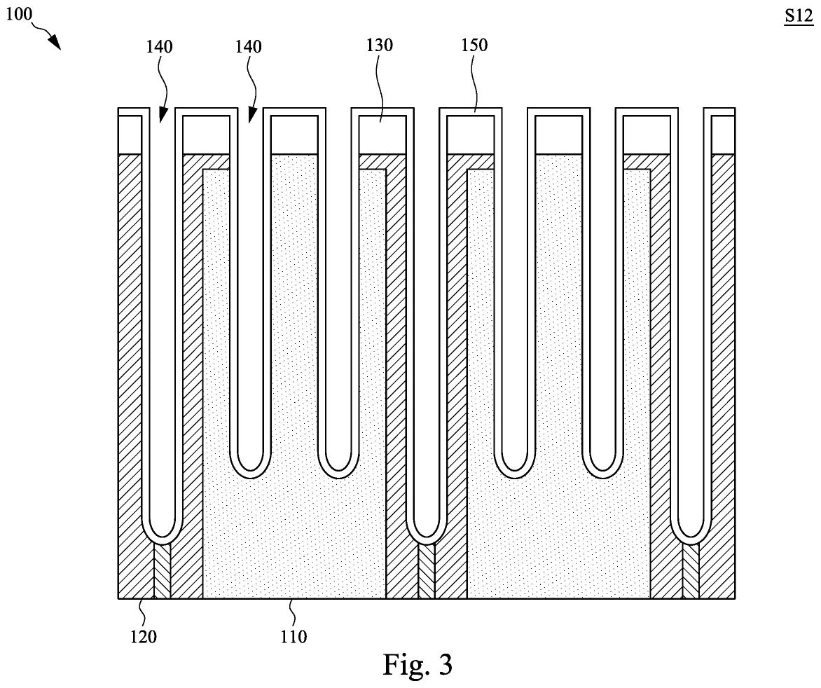

Reference is made to FIG. 3. As shown in step S12, a lining layer 150 is formed on sidewalls of the trenches 140 and on the hard mask layer 130. In some embodiments, the lining layer 150 is an oxide layer and is formed by an atomic layer deposition (ALD) process and an in-situ steam generation (ISSG) process such that the lining layer 150 is conformally formed on sidewalls of the trenches 140 and on the hard mask layer 130.

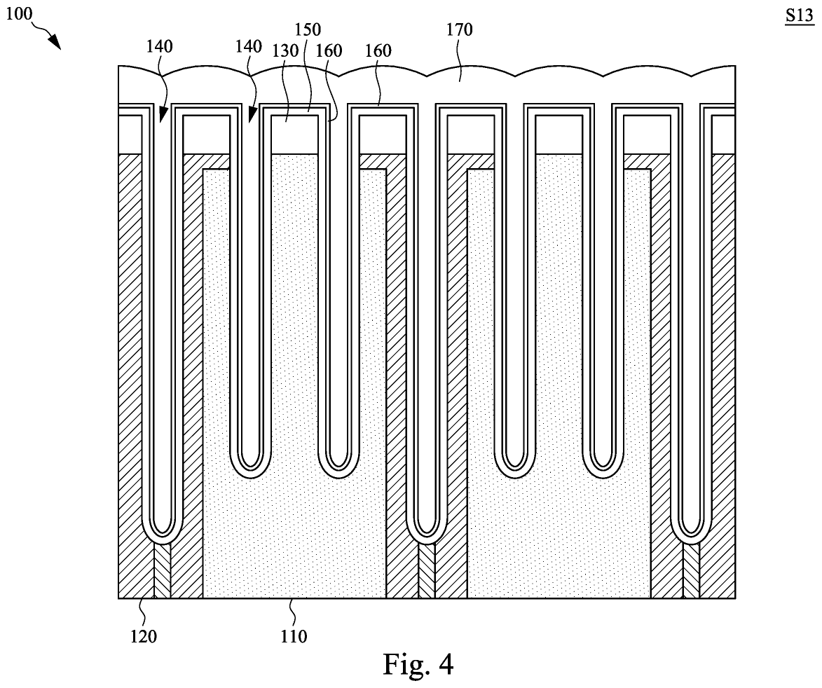

Reference is made to FIG. 4. As shown in step S13, a low work function material layer 160 is deposited. In addition, a conductive material layer 170 is deposited and fills the trenches 140 of the low work function material layer 160. In some embodiments, the low work function material layer 160 and the conductive material layer 170 not only fills the trenches 140 but also covers the hard mask layer 130 and the low work function material layer 160. In some embodiments, the conductive material layer 170 can be titanium nitride.

In some embodiments, the low work function material layer 160 can be formed by poly-silicon or amorphous silicon (a-Si).

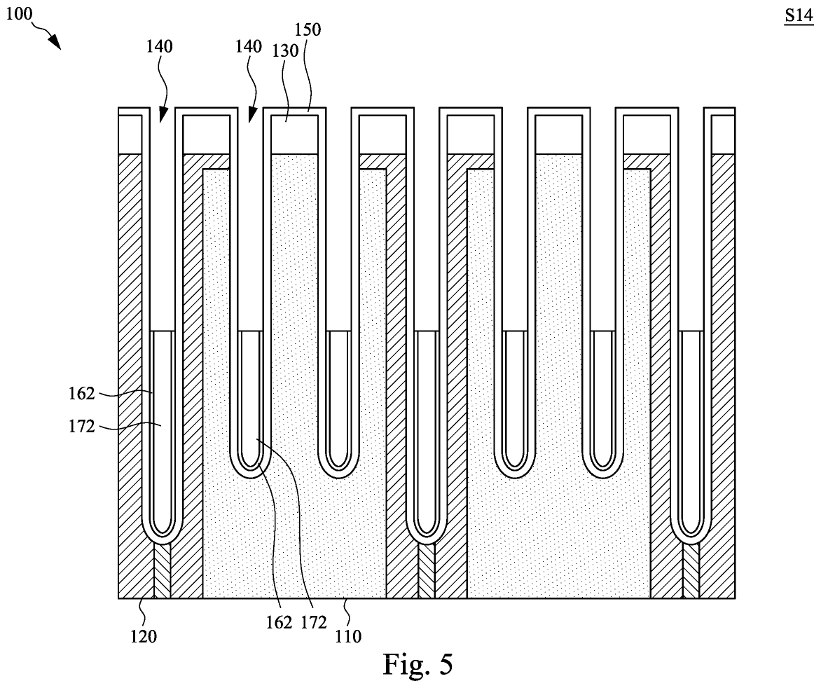

Reference is further made to FIG. 5. As shown in step S14, an etch back process is performed to remove portions of the low work function material layer 160 and the conductive material layer 170 in the trenches 140 and the low work function material layer 160 and the conductive material layer 170 over the hard mask layer 130. Portions of the low work function material layer 160 and the conductive material layer 170 are remained in the bottom of the trenches 140 to form a bottom low work function material layer 162 and a bottom conductive material layer 172. In some embodiments, the etch back process is a selective etching process which has a greater etching to the low work function material layer 160 and the conductive material layer 170 than the lining layer 150, thus the lining layer 150 is remained on the sidewalls of the trenches 140 after the etch back process is performed.

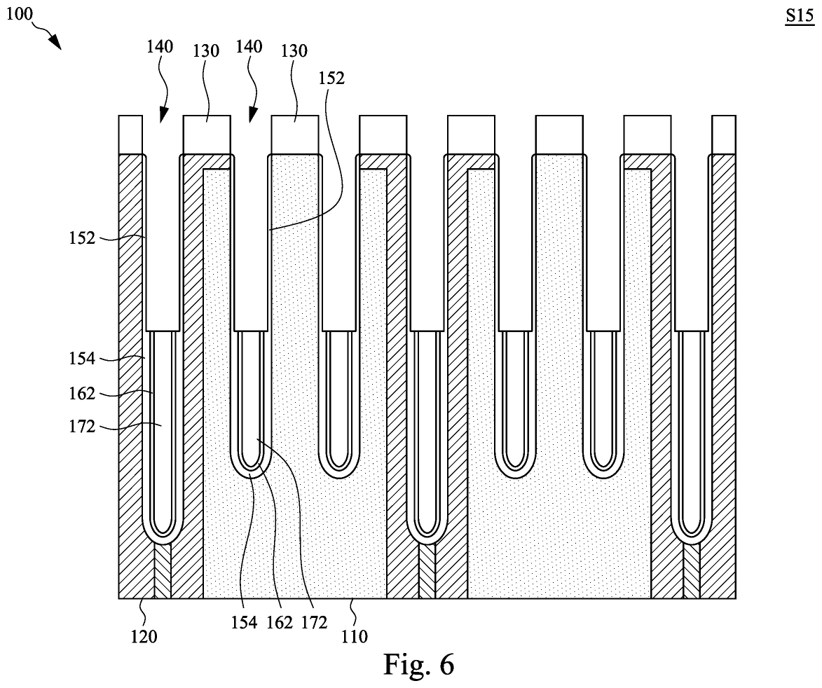

Reference is made to FIG. 6. As shown in step S15, a cleaning process is performed to remove residues of the low work function material layer 160 and the conductive material layer 170 on the sidewalls of the trenches 140, and portions of the lining layer 150 above the bottom low work function material layer 162 and the bottom conductive material layer 172 are removed during the cleaning process. In some embodiments, portions of the lining layer 150 above the bottom low work function material layer 162 and the bottom conductive material layer 172 on the sidewalls of the trenches 140 are also removed to form a residual lining layer 152.

In some embodiments, the cleaning process can be a wet cleaning process, including using dilute HF as an etchant. The portions of the lining layer 150 at the bottom of the trenches 140 are maintained to form a bottom lining layer 154 and the bottom lining layer 154 is sandwiched between the bottom low work function material layer 162 and the active regions 110 or between the bottom low work function material layer 162 and the isolation region 120.

In some embodiments, the residual lining layer 152 at top sections of the trenches 140 is not completely removed after the cleaning process is performed. Therefore, the sidewalls of the active regions 110 can be protected by the residual lining layer 152, and thus the loss of the active regions 110 can be prevented. In some other embodiments, the residual lining layer 152 at top sections of the trenches 140 is completely removed after the cleaning process is performed, and the sidewalls of the active regions 110 are exposed.

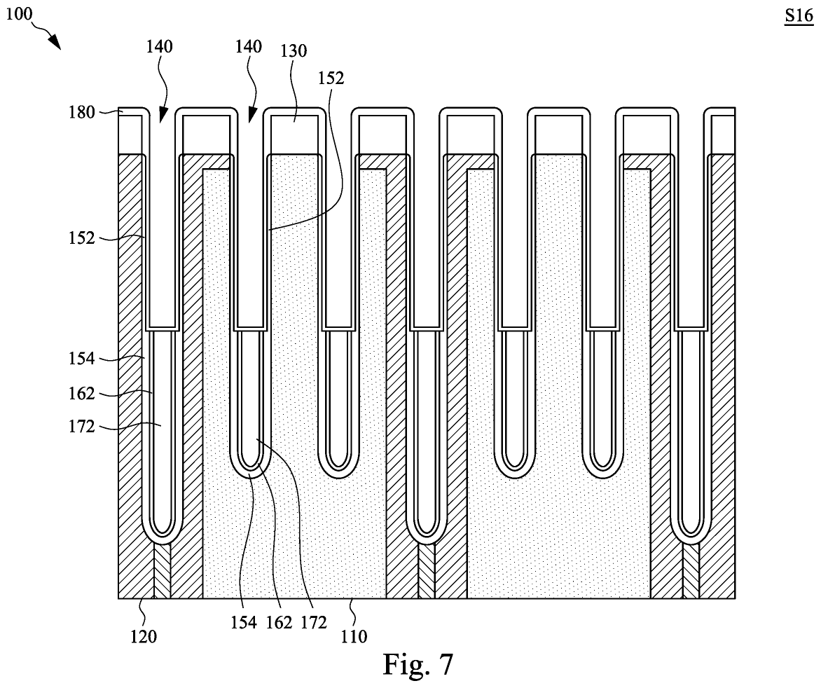

Reference is made to FIG. 7. As shown in step S16, a barrier layer 180 is formed on the hard mask layer 130, the trenches 140, and top surfaces of the bottom low work function material layer 162, the bottom conductive material layer 172 and the bottom lining layer 154. In some embodiments, the barrier layer 180 is formed by an atomic layer deposition process such that the barrier layer 180 is conformally formed on the hard mask layer 130, the sidewalls of the trenches 140, and the top surfaces of the bottom low work function material layer 162, the bottom conductive material layer 172 and the bottom lining layer 154.

In some embodiments, the trenches 140 are not completely filled by the barrier layer 180. In some embodiments, the barrier layer 180 may include the residual lining layer 152, if exists.

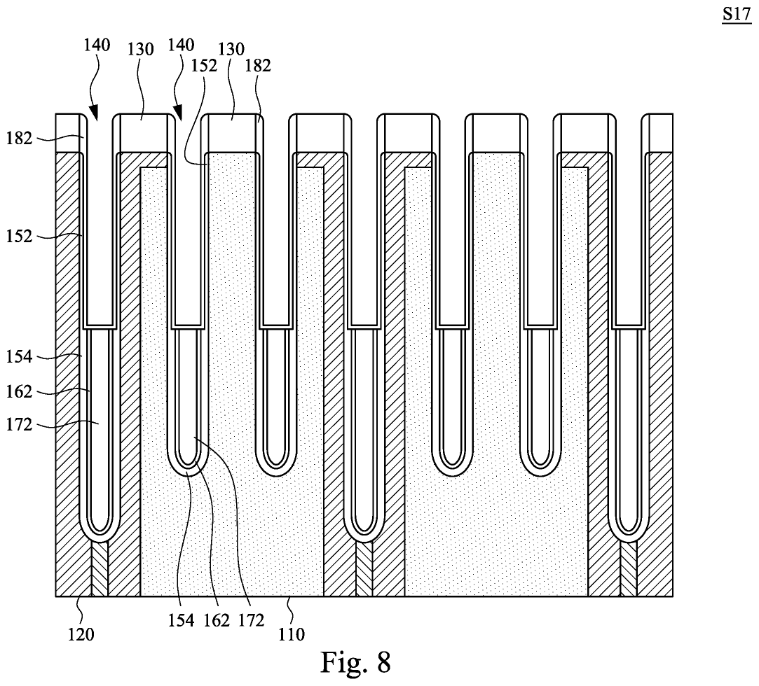

Reference is made to FIG. 8. As shown in step S17, a directional etching process is performed to remove lateral portions of the barrier layer 180 above the hard mask layer 130, and the vertical portions of the barrier layer 180 are remained on sidewalls of the trenches 140 to form a residual barrier layer 182.

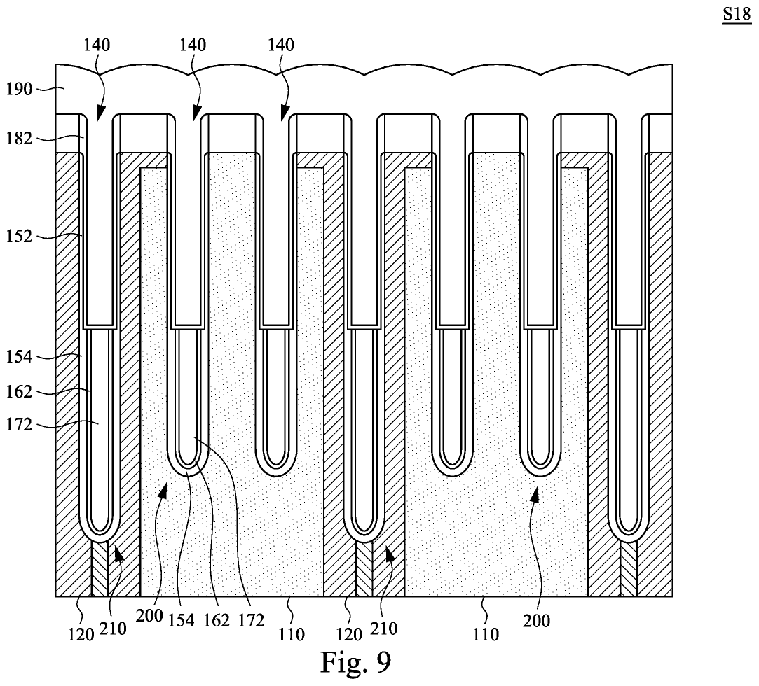

Reference is made to FIG. 9. As shown in step S18, a dielectric layer 190 is formed on the top surfaces of the active regions 110, the isolation region 120, the residual barrier layer 182 and the hard mask layer 130, and in the trenches 140.

Please refer to both FIG. 1 and FIG. 9. The semiconductor device 100 including the active regions 110, the isolation region 120, and the word lines WLs is provided. Each of the word lines WLs has a plurality of segments in the active regions 110, as the gate structures 200, and a plurality of segments in the isolation region 120, as the dummy gate structures 210. In some embodiments, the dummy gate structures 210 extend deeper than the gate structures 200.

Accordingly, the semiconductor device and the method of forming the same according to some embodiments of the present invention utilize the low work function material layer, e.g. a polycrystalline silicon layer or an amorphous silicon layer and a titanium nitride conductive material layer to effectively improve the gate-induced drain leakage current and reduce the resistance of the word line.

It will be apparent to those skilled in the art that various modifications and variations can be made to the structure of the present invention without departing from the scope or spirit of the disclosure. In view of the foregoing, it is intended that the present invention cover modifications and variations of this invention provided they fall within the scope of the following claims and their equivalents.

What is claimed is:

1. A semiconductor device, comprising:
a substrate;
an active region in the substrate; and
a gate structure in the active region, the gate structure comprising a bottom lining layer, a bottom low work function material layer formed in the bottom lining layer, and a bottom conductive material layer formed in the bottom low work function material layer.

2. The semiconductor device of claim 1, wherein a material of the bottom conductive material layer comprises titanium nitride.

3. The semiconductor device of claim 1, wherein a material of the bottom low work function material layer comprises a polycrystalline silicon or an amorphous silicon.

4. The semiconductor device of claim 1, wherein a material of the bottom lining layer comprises silicon oxide.

5. The semiconductor device of claim 1, further comprises a residual lining layer above the bottom lining layer and located higher than the bottom low work function material layer and the bottom conductive material layer.

6. The semiconductor device of claim 5, wherein a thickness of the residual lining layer is thinner than a thickness of the bottom lining layer.

7. The semiconductor device of claim 6, further comprising a barrier layer formed in the residual lining layer.

8. The semiconductor device of claim 7, further comprising a dielectric layer formed in the barrier layer.

9. The semiconductor device of claim 1, further comprising:
an isolation region in the substrate; and
a dummy gate structure in the isolation region, wherein the dummy gate structure extends deeper than the gate structure in the substrate.

10. The semiconductor device of claim 9, wherein the isolation region comprises an oxide layer directly in contact with the active region and a nitride layer sandwiched by the oxide layer.

11. A method of forming a semiconductor device, comprising:
forming an active region and an isolation region in a substrate;
forming a trench in the active region with a hard mask layer;
depositing a lining layer in the trench;
depositing a low work function material layer in the trench; and
depositing a conductive material layer to fill the trench.

12. The method of claim 11, further comprising:
etching back the conductive material layer and the low work function material layer to form a bottom conductive material layer and a bottom low work function material layer surrounding the bottom conductive material layer.

13. The method of claim 12, further comprising:
performing a cleaning process to remove a portion of the lining layer above the hard mask layer, a portion of the lining layer on a sidewall of the trench to form a residual lining layer and a bottom lining layer.

14. The method of claim 13, wherein the bottom lining layer is sandwiched between the bottom low work function material layer and the active regions or between the bottom low work function material layer and the isolation region.

15. The method of claim 14, wherein a thickness of the residual lining layer is thinner than a thickness of the bottom lining layer.

16. The method of claim 15, further comprising:
depositing a barrier layer on the hard mask layer and in the trench.

17. The method of claim 16, wherein the barrier layer is conformally formed on a sidewall of the trench, and top surfaces of the hard mask layer, the bottom low work function material layer, the bottom conductive material layer and the bottom lining layer.

18. The method of claim 17, wherein the barrier layer is formed by an atomic layer deposition process.

19. The method of claim 16, further comprising:
performing a directional etching process to remove lateral portions of the barrier layer above the hard mask layer and remain a residual barrier layer on a sidewall of the trench.

20. The method of claim 19, further comprising:
depositing a dielectric layer on the active region, the isolation region and the hard mask layer, and in the trenches.
